(19) United States
(12) Patent Application Publication
(10) Pub. No.: US 2003/0148618 A1
(43) Pub. Date: Aug. 7, 2003

(54) Selective metal passivated copper interconnect with zero etch stops

(75) Inventor: Suketu A. Parikh, San Jose, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 10/071,995

(22) Filed: Feb. 7, 2002

(51) Int. Cl. H01L 21/311

(52) U.S. Cl. 438/694

(57) ABSTRACT

In one aspect of the invention, a method for forming interconnects on a substrate is provided. A metal passivation layer is selectively formed on conductive elements of the substrate. Thereafter, one or more dielectric layers are deposited over the metal passivation layer. Interconnect lines and vias are then patterned and etched into the one or more dielectric layers. A conductive layer is subsequently deposited over the interconnect lines and vias. In another aspect of the invention, the selective deposition process may comprise electroless deposition of the metal passivation layer. Alternatively, the selective deposition process may comprise a selective chemical vapor deposition process. The metal passivation layer may also be formed by depositing a metal alloy of copper over the conductive element, depositing a copper layer over the metal alloy, and annealing the metal alloy. In another aspect still, a metal passivation layer is selectively deposited over the conductive element of the substrate. A first dielectric layer is then deposited over the metal passivation layer and the substrate. This is followed by depositing a second dielectric layer over the first dielectric layer. Preferably, the first dielectric layer has a dielectric constant higher than a second dielectric constant of the second dielectric layer. It is also preferred that the first and second dielectric layers have dissimilar etch characteristics. Interconnect lines and vias are then etched in the first and second dielectric layers using selective etch chemistry. The interconnect lines and vias are then filled with at least one conductive material.

### BACKGROUND OF THE INVENTION

1. Field of the Invention

Embodiments of the present invention generally relate to the formation of structures on a substrate. Specifically, embodiments relate to forming metal interconnects without etch stops.

2. Description of the Related Art

Advances in semiconductor materials and processing techniques have resulted in reducing the overall size of the integrated circuit (“IC”) while increasing the number of circuit elements. Additional miniaturization is highly desirable for improved IC performance and cost reduction. A key component of the IC is the interconnects. Interconnects provide the electrical connections between the various electronic elements of an IC and between these elements and the device's external contact elements, such as pins, for connecting the IC to other circuits. Typically, interconnect lines form the horizontal connections between the electronic elements while interconnect vias form the vertical connections between the electronic elements or between an electronic element and an external contact element.

A variety of techniques are employed to create interconnect lines and vias. One such technique is a damascene process. In a damascene process, trenches are first patterned into a dielectric material. Then a conductive material is deposited into the lines or vias. Another technique is the dual damascene process in which lines and vias are patterned at different levels and then simultaneously filled with a conductive material such as copper.

A conventional dual damascene method for fabricating interconnect lines and vias in an integrated circuit is illustrated in FIGS. 1A-1E. FIG. 1A illustrates a planarized semiconductor substrate 100 having a bottom layer 110 that includes conductive elements 112. Referring to FIG. 1B, a first etch stop layer 120 is deposited over the bottom layer 110 and conductive elements 112. The first etch stop layer 120 preferably comprises silicon nitride. Typically, the first etch stop layer 120 also serves as a passivation layer. Thereafter, a first dielectric layer 130 is deposited over the first etch stop layer 120. This is followed by deposition of a second etch stop layer 140 over the first dielectric layer 130. A photoresist layer (not shown) is formed over the second etch stop layer 140 and is patterned to define the vias 145. After the vias 145 are defined in the etch stop layer 140, the photoresist is removed. Referring to FIG. 1C, a second dielectric layer 150 is then deposited over the second etch stop layer 140. Another photolithography process is performed to define the lines 155 in the second dielectric layer 150 and the vias 145 in the first dielectric layer 130. The etch chemistry used to form the lines 155 and the vias 145 is selective for the dielectric material over the etch stop layers 120, 140. This selectivity is necessary to prevent over-etching of the first dielectric layer 130 while forming the lines 155 and to prevent over-etching of the bottom layer 110 while forming the vias 145. Thereafter, the first etch stop layer 120 is etched to expose the underlying metal lines as illustrated in FIG. 1D. Referring to FIG. 1E, a barrier layer 160 is then conformally deposited over the patterned substrate to prevent copper from diffusing into the dielectric layers 130, 150. The barrier layer 160 is followed by a copper layer 170 to completely fill the trench 155 and via 145. The excess copper 170 and barrier layer 160 are removed and the surface planarized. Finally, a passivation layer 180 is deposited over the polished surface as shown in FIG. 1E.

The development of the dual damascene process has increased the use of copper as a conductive material in IC. Although copper is a better material for interconnect lines and vias because of its low resistivity property, copper is more difficult to etch than aluminum. Traditional deposition and patterning techniques require some form of etching of the conductive material. As seen above, the dual damascene process does not involve any etching of the conductive material. As a result, the dual damascene process has allowed copper to become the conductive material of choice for interconnect lines and vias.

Conductive materials, such as copper, having a lower resistivity are desirable for interconnects because they increase the IC performance. Another factor that determines IC performance is capacitance. Lower capacitance is ideal because it reduces cross-talk between the metal lines. One way to reduce capacitance of the IC is to use dielectric materials with a low dielectric constant. In a dual damascene structure, the etch stop layer usually has a higher dielectric constant than the dielectric material. The prior art dual damascene example above contains two etch stop layers 120, 140. Thus, it would be desirable to eliminate the etch stop layer.

Therefore, there is a need for a method of forming dual damascene structures on a substrate with increase reliability and performance.

### SUMMARY OF THE INVENTION

The embodiments of the present invention provide a method of forming interconnects without the use of etch stop layers. In one aspect of the invention, a method for forming interconnects on a substrate is provided. A metal passivation layer is selectively formed on conductive elements of the substrate. Thereafter, one or more dielectric layers are deposited over the metal passivation layer. The one or more dielectric layers having dissimilar etch characteristics. Interconnect lines and vias are then patterned and etched into the one or more dielectric layers. A barrier layer is subsequently deposited over the interconnect lines and vias. A conductive layer is then deposited over the barrier layer to fill the lines and the vias.

In another aspect of the invention, the metal passivation layer may be deposited using an electroless deposition process. Alternatively, the metal passivation layer may be deposited using a selective chemical vapor deposition process. The metal passivation layer may also be formed by depositing a metal alloy of copper. The metal alloy is deposited in the via over the barrier layer. Subsequently, a copper layer over the metal alloy to fill the via. The metal alloy is annealed to separate the alloy to the top of the via thereby forming the metal passivation layer.

In still another aspect, a metal passivation layer is selectively deposited over a conductive element formed on a substrate. A first dielectric layer is then deposited over the metal passivation layer and the substrate. A second dielectric layer is then deposited over the first dielectric layer. Preferably, the first dielectric layer has a dielectric constant higher than a second dielectric constant of the second dielectric layer. It is preferred that the first and second dielectric layers have dissimilar etch characteristics. The via is then etched through the first and second dielectric layers to expose the metal passivation layer. Taking advantage of the dissimilar etch characteristics, an etch chemistry selective for the second dielectric layer is used to form the line in the second dielectric layer. The line etch will stop on the first dielectric layer because of the etch selectivity. The interconnect lines and vias are then filled with at least one conductive material.

### BRIEF DESCRIPTION OF THE DRAWINGS

So that the manner in which the above recited features, advantages and objects of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIGS. 1A-1E are schematic drawings of the formation of a structure on a substrate in the prior art.

FIGS. 2-7 are schematic drawings of the formation of a structure on a substrate according to an embodiment of the present invention.

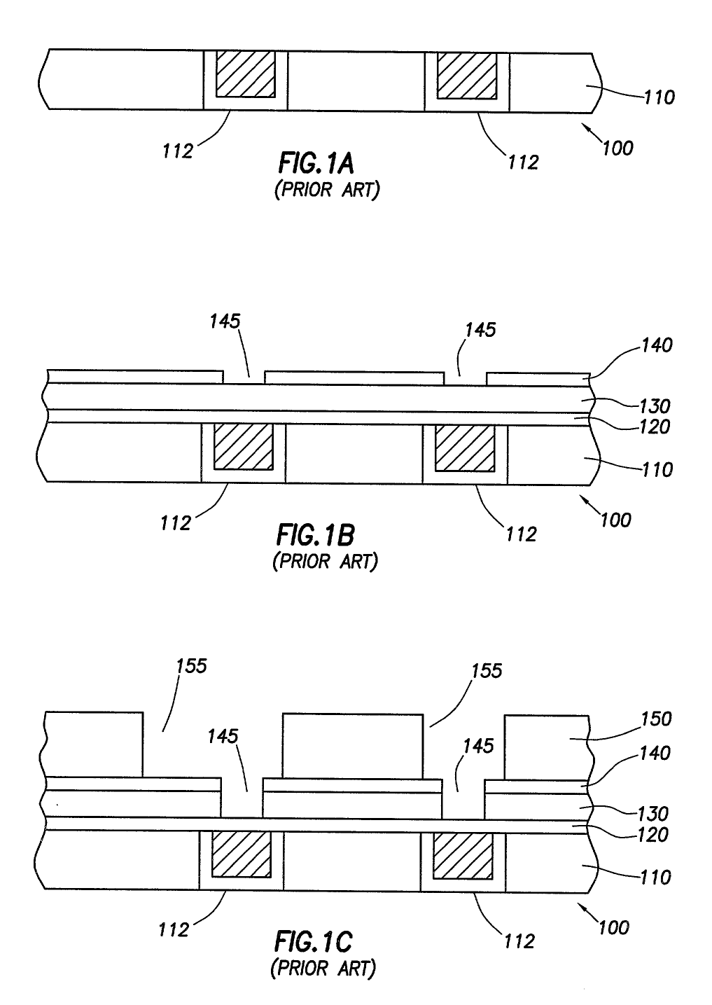

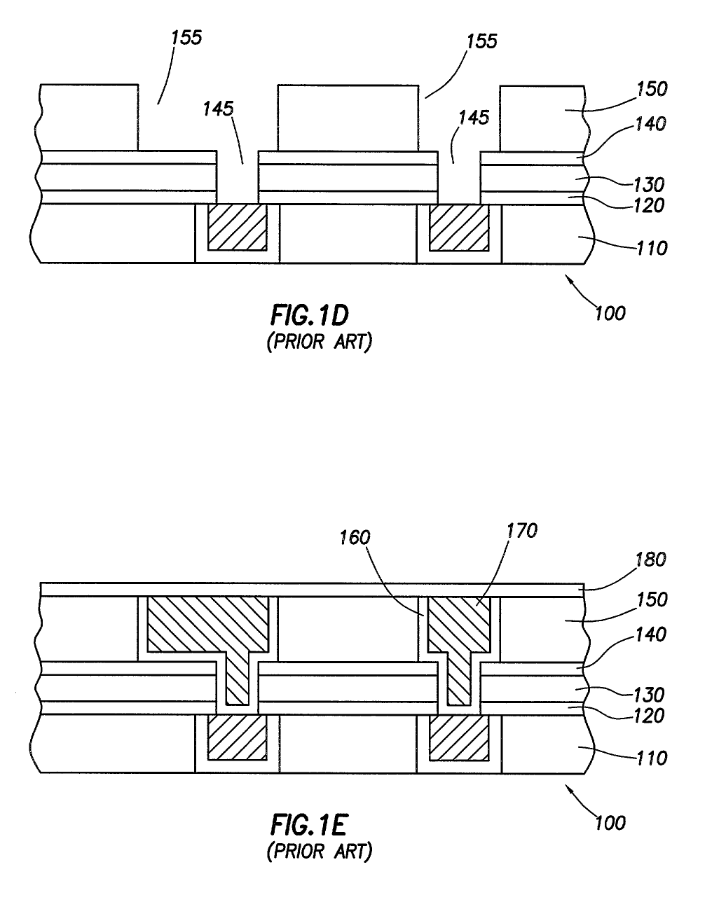

### DETAILED DESCRIPTION OF THE PREFERRED EMBODIMENT

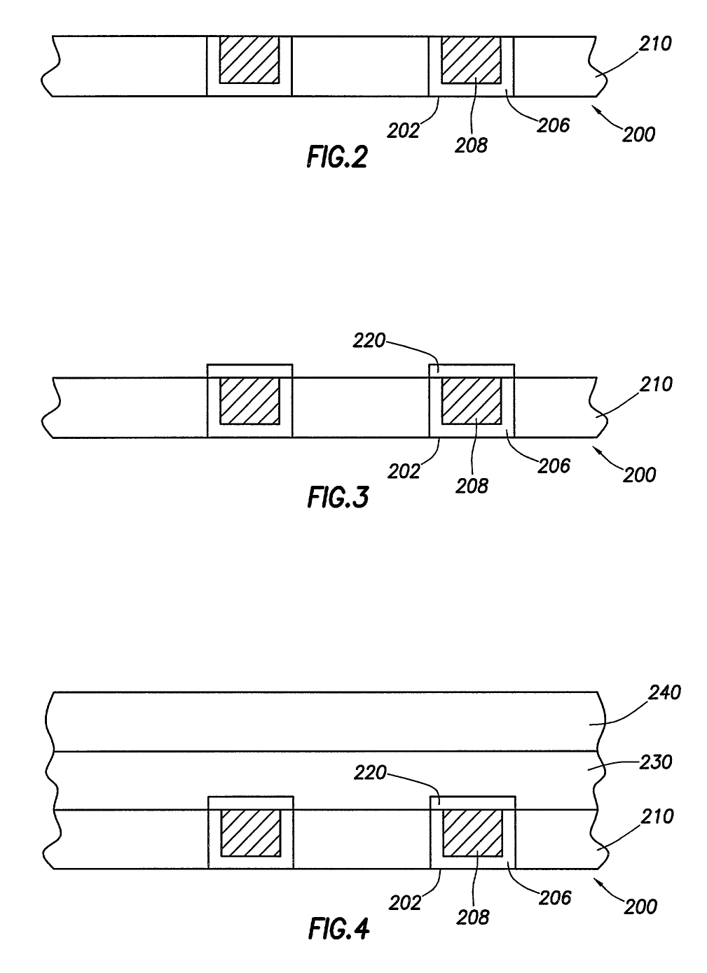

FIG. 2 illustrates substrate 200 having conductive elements 206, 208 formed thereon. For example, a first dielectric layer 210 is initially deposited. A feature 202 is then patterned and etched in the first dielectric layer 210 by a photolithography process. After the feature 202 is formed, a barrier layer 206 is deposited over the first dielectric layer 210. A conductive material 208, such as copper, is then deposited over the barrier layer 206 to fill the feature 202. Excess conductive material may be removed by planarization processes such as chemical mechanical polishing. After planarization, additional metallization layers may be deposited.

In one aspect of the present invention, as illustrated in FIG. 3, a metal passivation layer 220 is formed on the conductive elements 206, 208 using a selective deposition process. The metal chosen for the metal passivation layer 220 is required to be a barrier to diffusion of the conductive material 208. In one embodiment, the selective process used to passivate copper is an electroless deposition process. Electroless deposition occurs without the use of an electrical field or bias. It has been shown that an electroless deposition process will selectively deposit metal onto other metal surfaces. Electroless deposition of the metal 220 preferentially forms a layer on the conductive material 208 surface and not on the surrounding dielectric material 210, thereby forming the metal passivation layer 220 selectively over the conductive elements 206, 208. Metals like palladium, tin, nickel, platinum, chromium, manganese, or combinations thereof can be electrolessly deposited onto other metal surfaces to form the metal passivation layer 220.

The metal passivation layer 220 can also be deposited by a selective chemical vapor deposition process. Generally, this process requires nucleation on the conductive element, such as the copper surface and the exposed barrier surface. Once nucleation occurs, the process will continue to selectively deposit the metal onto the conductive element and not on the dielectric material 210. Examples of metals that can be deposited in this manner include tantalum nitride, titanium nitride, tungsten, titanium silicon nitride, titanium, tantalum, or a combination thereof. Any loss of selectivity resulting in deposition on the dielectric material 210 can be removed by chemical mechanical polishing or electro-chemical mechanical polishing techniques.

In yet another embodiment, the metal passivation layer 220 may comprise a copper alloy. Referring back to FIG. 2, after depositing a barrier layer 206, a copper alloy is deposited as a seed layer into the via by physical vapor deposition over the barrier layer 206. Thereafter, copper 208 is deposited to fill the via. The deposited copper alloy is subsequently annealed. Upon annealing, the metal alloys will segregate from the copper 208 and diffuse to the outer perimeters and surround the copper 208. It has been shown that a higher portion of the metal alloy will diffuse across the top surface and form a passivation layer (not shown) over the copper 208. The passivation layer formed is flush with the top surface of the dielectric layer 210 after planarization. Metals that may form alloys with copper that are suitable for this process include magnesium, zirconium, lead, cobalt, chromium, tin, and a combination thereof.

Following the formation of the metal passivation layer 220, a second dielectric layer 230 is deposited over the passivation layer 220 and the first dielectric layer 210 as illustrated in FIG. 4. Preferably, the second dielectric layer 230 has a dielectric constant that is higher than that of the first dielectric layer 210. Because an interconnect via will be formed in the second dielectric layer, a slightly higher dielectric constant is advantageous because it offers better mechanical strength, better thermal conductivity, and a more stable interconnect. The preferred range of the dielectric constant of the second dielectric layer is between about 2 and about 5. A lower dielectric constant is preferred in the first dielectric layer because it contains an interconnect line. A low dielectric constant film provides better circuit performance because it has lower capacitance. Capacitance is a factor limiting the speed of a signal traveling along interconnect lines. Therefore, interconnect lines formed in dielectric layers with low electric constants have a smaller time delay and better circuit performance. The preferred range of the first dielectric layer is between about 1.2 and about 3.8.

Since the second dielectric layer 230 is deposited over the first dielectric layer 210 without the etch stop layer, it may be possible to etch the first dielectric layer 210 when a feature is formed in the second dielectric layer 230. To prevent over-etching, the first dielectric layer 210 and second dielectric layer 230 should have dissimilar etch characteristics. In other words, one dielectric layer has a higher etch rate than the other using a specific etch chemistry. The dissimilar etch characteristics allow for the use of a selective etch chemistry to etch features on the second dielectric layer 230 and without substantially etching the first dielectric layer 210. Thus, dielectric layers having dissimilar etch characteristics are advantageous in forming features in the dielectric layers because etching can be controlled without the use of etch stop layers. For example, a feature, such as a via, can be etched in the second dielectric layer 230 using an etch chemistry selective for the second dielectric layer 230. Because the chemistry is selective, the etch process will stop when it reaches the first dielectric layer 220, thereby eliminating the need for an etch stop layer.

A third dielectric layer 240 is then deposited over the second dielectric layer 230 without depositing an etch stop layer between the two dielectric layers 230, 240. Interconnect lines are formed in the third dielectric layer 240. Thus, the third dielectric layer 240 should have the same characteristics as the first dielectric layer 210, e.g., have dissimilar etch characteristics with the second dielectric layer 230 and a lower dielectric constant than the second dielectric layer 230.

Suitable dielectric layers include silicon oxide layers, such as doped silicon oxide layers, deposited by chemical vapor deposition or plasma enhanced chemical vapor deposition as described in U.S. Pat. No. 6,054,379. Doped silicon oxide layers include silicon oxide layers doped with carbon or fluorine. Other suitable dielectric materials include silicon carbide materials, amorphous fluorinated carbon based materials, fluorinated poly(arylene) ether, poly(arylene) ethers, spin-on polymers, and aero-gels.

In the aspect shown in FIG. 5, the interconnect via 245 is first patterned and etched through the second dielectric layer 230 and third dielectric layer 240 to expose the top of the metal passivation layer 220. As illustrated in FIG. 5, if the via 245 formed is misaligned, a portion 215 of the first dielectric layer 210 will be exposed.

The interconnect via may be formed in two etch steps. The third dielectric layer 240 is first etched through using an etch process that is selective for the third dielectric layer 240 to expose the second dielectric layer 230. The initial etch will stop on the second dielectric layer 230 because it has dissimilar etch characteristics from the third dielectric layer 240. Then, the interconnect via 245 is etched in the second dielectric layer 230 using an etch process that is selective for the second dielectric layer 230. Taking advantage of dissimilar etch properties between the first and second dielectric layers 210, 230, the via etch will stop on the metal passivation layer 220 or the first dielectric layer 210 if misaligned. Slight etching of the metal passivation layer 220 will not negatively affect the integrity and function thereof and of the device and/or structure being formed. Consequently, an etch stop layer between the first and second dielectric layers is not necessary according to the embodiments of the present invention.

Alternatively, the via 245 may be etched in one step. Generally, when the etch stop layer is present, a separate etch chemistry is used to etch the etch stop layer. Because the embodiments of the present invention do not contain etch stop layers, one etch chemistry may be selected to effectively etch both the second and the third dielectric layers 230, 240. However, this etch chemistry may also etch the first dielectric layer 210. To prevent over-etching into the first dielectric layer 210, the etch process time may be controlled to stop the etch on the metal passivation layer 220 or the first dielectric layer 210.

After the interconnect vias 245 are etched and the metal passivation layers 220 are exposed, the interconnect lines 247 are patterned and etched. In the case of a misaligned via 245 wherein a portion 215 of the first dielectric layer is exposed, the bottom of the via 245 is deposited with bottom arc or other dielectric protection material (not shown) before the lines 247 are etched. The exposed portion 215 of the first dielectric layer 210 is protected from the line etch because the first dielectric layer 210 and the third dielectric layer 240 may have similar etch properties. After patterning, the lines 247 are etched using an etch process that is selective for the third dielectric layer 240 over the second dielectric layer 230. A selective etch process can be used because the two layers have dissimilar etch properties. Using a selective etch process to stop the line etch on the second dielectric layer 230 will eliminate the need of an etch stop layer between the second dielectric layer 230 and the third dielectric layer 240. Thereafter, the dielectric protective material is removed.

By eliminating the etch stop layer, the process of forming structures on a substrate is more efficient. The etch stop layer is generally a dielectric layer with a dielectric constant higher than the intermetal dielectric layers. Thus, a structure formed without an etch stop according to aspects of the invention described herein will have a lower overall capacitance and increased circuit performance. Furthermore, eliminating the etch stop layer reduces the number of deposition and etching processes, thereby increasing throughput and decreasing the cost of manufacturing.

In another aspect of the invention, a dual damascene structure can be formed in one dielectric layer (not shown). After the metal passivation layer is selectively deposited on the underlying conductive element, a second dielectric layer is deposited over the metal passivation layer and the first dielectric layer. Preferably, the first and second dielectric layers have dissimilar etch characteristics so that over-etching can be avoided by using selective chemistry. Initially, the via is first etched through the second dielectric layer using an etch process selective to the second dielectric layer to expose the metal passivation layer or a portion of the first dielectric layer if the via is misaligned. A second etch is performed to form the line in the second dielectric layer. In this instance, a selective etch chemistry is not applicable because the via and the line are formed in the same dielectric layer. Instead, a timed etch is used maintain the depth of the line and avoid over-etching.

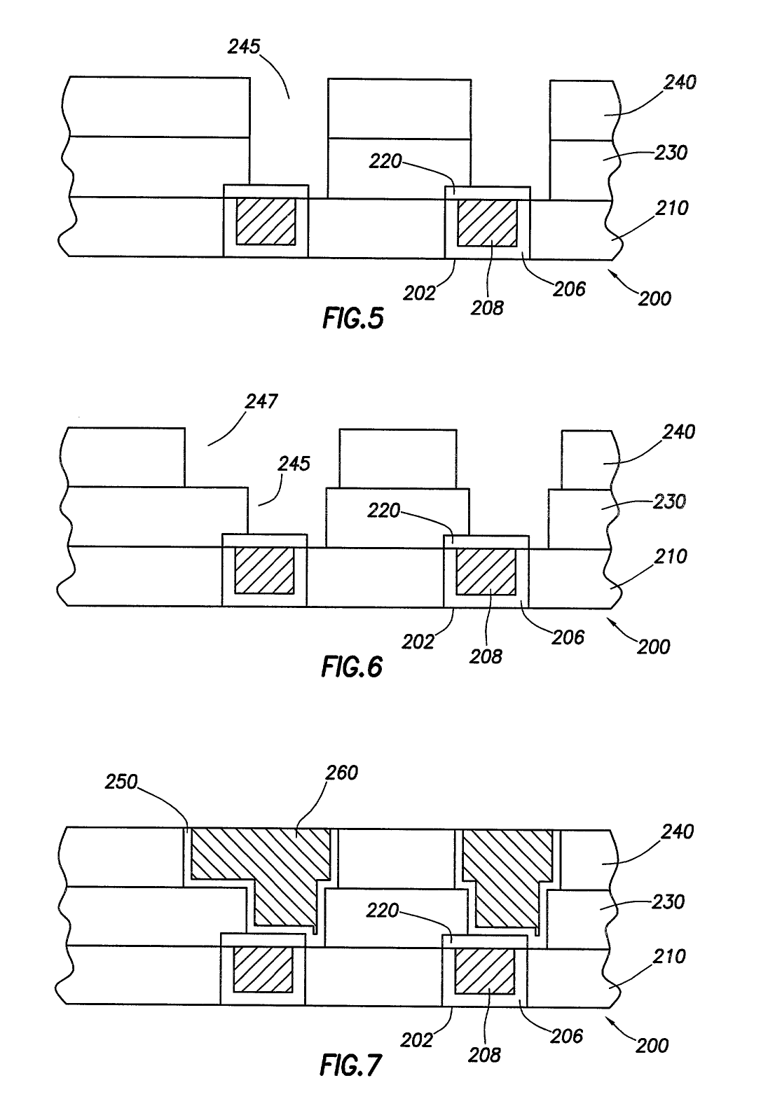

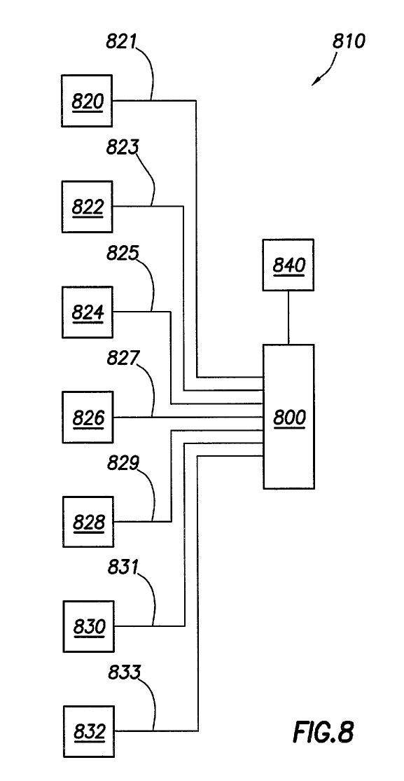

After the features are formed and the photoresist is removed, a barrier layer is deposited as illustrated in FIG. 7. The barrier layer 250 is formed over the substrate 200 in such a manner as to cover all the exposed surfaces of the substrate 200, including the topmost surface of the dielectric layers, the sidewalls of the features, and the bottom of the features. The barrier layer 250 can be deposited by physical vapor deposition, chemical vapor deposition, or other methods known in the art. The barrier layer 250 preferably comprises titanium, tantalum, titanium nitride, tantalum, tantalum nitride, tungsten nitride, metal nitrides, or combinations thereof. Other barrier materials which is known or become known may also be used.

In another aspect (not shown), the portion of the passivation layer that is exposed in the via may be removed prior to barrier layer deposition. One purpose of the metal passivation layer is to prevent the conductive metal from diffusing into the dielectric. Generally, barrier layers are deposited for this same purpose. Since the barrier layer is typically deposited over the surfaces of the via, including the exposed portion of the passivation layer, the result is having two metal layers preventing diffusion. Thus, the exposed passivation layer may be removed before depositing the barrier layer. The removal of the passivation layer will eliminate a metal interface and lower the via resistance.

A layer of conductive metal 260 is deposited over the barrier layer 250. The conductive metal 260 may comprise copper, aluminum, alloys thereof, or other conductive materials. The conductive metal 260 may be deposited by chemical vapor deposition, physical vapor deposition, electrochemical plating, electroless plating, or combinations thereof. The conductive metal 260 may be deposited in two steps including first depositing a seed layer followed by another layer to fill the feature. Any excess metal 260 can be removed by chemical mechanical polishing or other techniques known in the art. After planarization, the substrate 200 is ready for further processing.

Aspects of the present invention require a sequence of processing steps. Each processing step can be performed at a fabrication station. All or some of the fabrication stations and their respective processing steps can be integrated by means of a novel apparatus including a controller 800 illustrated in FIG. 8. Controller 800 is adapted for controlling a number of fabrication stations which are utilized in the formation of fabricated structures, such as the IC structures described in connection with FIGS. 2-7. As illustrated in FIG. 8, a novel manufacturing system 810 for fabricating IC structures includes controller 800 and a plurality of fabrication stations: 820, 822, 824, 826, 828, 830 and 832. Additionally, system 810 has operative links 821, 823, 825, 827, 829, 831 and 833 which provide connections between controller 800 and fabrication stations 820, 822, 824, 826, 828, 830 and 832 respectively. The novel apparatus includes a data structure such as a computer program which causes controller 800 to control the processing steps at each of the fabrication stations and to, optionally, regulate the sequence in which fabrication stations are used in order to form the novel structures.

Examples of suitable controllers include conventional computers and computer systems including one or more computers which are operably connected to other computers or to a network of computers or data processing devices. Suitable computers include computers commonly known as personal computers. The data structure which is used by controller 800 can be stored on a removable electronic data storage medium 840 (FIG. 8), such as computer floppy disks, removable computer hard disks, magnetic tapes and optical disks, to facilitate the use of the same data structure at different manufacturing locations. Alternatively, the data structure can be stored on a non-removable electronic data storage medium, including a medium positioned at a location which is remote (not shown) from controller 800, using such data storage devices as are well known to those or ordinary skill in the art. The data structure can be communicated from a remote location to controller 800 using communicating techniques which are well known to those of ordinary skill in the art including hard wire connections, wireless connections and data communication methods utilizing one or more modems or techniques using one or more computers commonly known as servers. The data storage medium can be operably connected to the controller using methods and device components which are well known to those of ordinary skill in the art. Examples of suitable fabrication stations for manufacturing system 810 include the stations shown in Table I.

TABLE I

| Station | Processing Step |
|---|---|
| 820 | Forming a conductive element on a substrate comprising a first |
| | dielectric layer and one or more conductive material embedded |
| | in the first dielectric layer |
| 822 | Selectively depositing a metal passivation layer on the |
| | conductive element |
| 824 | Depositing a second dielectric layer over the metal passivation |
| | layer and the first dielectric layer |
| 826 | Depositing a third dielectric layer over the second |
| | dielectric layer |
| 828 | Forming a via in the second dielectric layer |
| 830 | Forming a line in the third dielectric layer |
| 832 | Depositing a conductive material in the line and the via |

The fabrication stations may be integrated on different platforms, such as a dielectric platform or a chemical mechanical polishing platform. For example, fabrication station 822 may be integrated with fabrication station 824 on the dielectric platform. The controller may be adapted to control the sequence of fabrication stations located on different platforms. The computer program may cause the controller to regulate the movement of a substrate from one fabrication station to another fabrication station on the same platform. Thereafter, the controller may cause the controller to sequentially move the substrate from that fabrication station to another fabrication station located on different platform.

Additional fabrication stations can be added to manufacturing system 810, for example one or more planarizing stations. The sequence of processing steps shown in Table I is illustrative of system 810. However, the invention is equally operable in systems wherein a controller, such as controller 800, causes the sequence to be altered, for example by repeating a previously executed processing step if test results indicate that this processing step should be partly or completely repeated. Alternatively, the process sequence which is controlled by a controller such as controller 800, can include processing steps such as surface preparation which may be performed following any of the fabrication stations shown in FIG. 8 and Table I. It is also contemplated that one or more fabrication stations can be positioned at a location which is remote from the other fabrication stations in which case an additional controller or a network of controllers can be employed to control the remotely located manufacturing station.

As illustrated in FIG. 8, controller 800 is adapted to be connected to each of the manufacturing stations through operative links. Each of these links provides a bidirectional connection enabling controller 800 to transfer commands from its data structure, such as specific operating parameters, and to receive information, such as test data, from the fabrication station. The operative links can be in the form of hard wire connections or wireless connections.

While the foregoing is directed to embodiments of the present invention, other and further embodiments of the invention may be devised without departing from the basic scope thereof, and the scope thereof is determined by the claims that follow.

1. A method of forming a structure on a substrate, comprising:
selectively depositing a metal passivation layer over a conductive element in the substrate;
depositing one or more dielectric layers over the metal passivation layer and the substrate; and
forming at least one interconnect line and at least one interconnect via in the one or more dielectric layers.

2. The method of claim 1, wherein depositing one or more dielectric layers comprises:
depositing a first dielectric layer over the metal passivation layer and the substrate; and
depositing a second dielectric layer over the first dielectric layer, wherein a dielectric constant of the first dielectric layer is greater than a dielectric constant of the second dielectric layer.

3. The method of claim 2, wherein forming a feature comprises:
forming a via in the first and second dielectric layers; and
forming a line in the second dielectric layer using an etch process that is selective for the second dielectric layer over the first dielectric layer.

4. The method of claim 3, wherein forming a via comprises;
etching the via in the second dielectric layer using an etch process that is selective for the second dielectric layer over the first dielectric layer; and
etching the via in the first dielectric layer using an etch process that is selective for the first dielectric layer over the second dielectric layer.

5. The method of claim 2, further comprising:
depositing a barrier layer; and
depositing a conductive material.

6. The method of claim 2, wherein wherein the dielectric constant of the first dielectric layer is between about 2 and about 5, and the dielectric constant of the second dielectric layer is between about 1.2 and about 3.8

7. The method of claim 1, wherein the metal passivation layer is also barrier layer.

8. The method of claim 1, wherein selectively depositing a metal passivation layer comprises electroless deposition of the metal passivation layer.

9. The method of claim 8, wherein the metal passivation layer comprises a metal selected from the group consisting of palladium, tin, nickel, platinum, chromium, and manganese.

10. The method of claim 1, wherein selectively depositing a metal passivation layer comprises selectively chemical vapor depositing a metal selected from the group consisting of tungsten, tantalum nitride, titanium nitride, titanium silicon nitride, or a combination thereof.

11. The method of claim 1, wherein selectively depositing a metal passivation layer comprises:
depositing a copper alloy;
depositing a copper layer over the copper alloy; and
annealing the copper alloy.

12. The method of claim 10, wherein the copper alloy comprises copper and a metal selected from the group consisting of magnesium, zirconium, lead, cobalt, chromium, and tin.

13. The method of claim 1, wherein only one dielectric layer is deposited over the metal passivation layer and forming interconnect lines and interconnect vias comprises:
etching the vias in the dielectric layer; and
etching the lines in the dielectric layer, wherein a depth of the lines is controlled by controlling an etch process time.

14. The method of claim 1, wherein the metal passivation layer comprises a metal selected from the group consisting of tungsten, tantalum nitride, titanium nitride, titanium silicon nitride, or a combination thereof.

15. The method of claim 1, further comprising:
depositing a barrier layer; and
depositing a conductive material.

16. A method for forming a dual damascene structure on a substrate, comprising:
selectively depositing a metal passivation layer over a conductive element in the substrate, wherein the metal passivation layer prevents the diffusion of a conductive metal across the metal passivation layer;
depositing a first dielectric layer over the metal passivation layer and the substrate;
depositing a second dielectric layer over the first dielectric layer;
forming a via in the first dielectric layer; and
forming a line in the second dielectric layer.

17. The method of claim 16, wherein a dielectric constant of the first dielectric layer is greater than a dielectric constant of the second dielectric layer.

18. The method of claim 17, wherein the dielectric constant of the first dielectric layer is between about 2 and about 5, and the dielectric constant of the second dielectric layer is between about 1.2 and about 3.8.

19. The method of claim 17, wherein selectively depositing a metal passivation layer comprises electroless deposition of the metal passivation layer.

20. The method of claim 17, wherein selectively depositing a metal passivation layer comprises selectively chemical vapor depositing a metal selected from the group consisting of tungsten, tantalum nitride, titanium nitride, titanium silicon nitride, or a combination thereof.

21. The method of claim 17, wherein selectively depositing a metal passivation layer comprises:
depositing a copper alloy layer;
depositing a copper over the copper alloy; and
annealing the copper alloy layer.

22. The method of claim 17, further comprising:
depositing a barrier layer over the interconnect lines and vias;
depositing a conductive layer over the barrier layer.

23. A method for forming a structure on a substrate, comprising:
forming a conductive element on the substrate, comprising:
a first dielectric layer;
one or more conductive element embedded in the first dielectric layer;
selectively depositing a metal passivation layer over the one or more conductive element;
depositing a second dielectric layer over the metal passivation layer and the first dielectric layer;
depositing a third dielectric layer over the second dielectric layer, wherein a dielectric constant of the third dielectric layer is less than a dielectric constant of the second dielectric layer;
forming a via in the second dielectric layer; and
forming a line in the third dielectric layer.

24. The method of claim 23, wherein forming a via comprises:
etching the via in the third dielectric layer using an etch process that is selective for the third dielectric layer over the second dielectric layer; and
etching the via in the second dielectric layer using an etch process that is selective for the second dielectric layer over the third dielectric layer.

25. The method of claim 23, wherein a dielectric constant of the first dielectric layer is less than a dielectric constant of the second dielectric layer.

26. The method of claim 25, wherein forming a via comprises:
etching the via in the third dielectric layer using an etch process that is selective for the third dielectric layer over the second dielectric layer; and
etching the via in the second dielectric layer using an etch process that is selective for the second dielectric layer over the third dielectric layer.

27. The method of claim 26, wherein selectively depositing a metal passivation layer comprises electroless deposition of the metal passivation layer.

28. The method of claim 26, wherein selectively depositing a metal passivation layer comprises selectively chemical vapor depositing a metal selected from the group consisting of tungsten, tantalum nitride, titanium nitride, titanium silicon nitride, or a combination thereof.

29. The method of claim 26, wherein selectively depositing a metal passivation layer comprises:
depositing a copper alloy;
depositing a copper layer over the copper alloy; and
annealing the copper alloy.

30. The method of claim 26, further comprising:
removing a portion of the metal passivation layer exposed in the via;
depositing a conductive metal in the via.

31. The method of claim 30, wherein selectively depositing a metal passivation layer comprises electroless deposition of the metal passivation layer.

32. The method of claim 30, wherein selectively depositing a metal passivation layer comprises selectively chemical vapor depositing a metal selected from the group consisting of tungsten, tantalum nitride, titanium nitride, titanium silicon nitride, or a combination thereof.

33. The method of claim 30, wherein selectively depositing a metal passivation layer comprises:
depositing a copper alloy;
depositing a copper layer over the copper alloy and
the copper alloy.

34. The method of claim 23, further comprising:
depositing a barrier layer; and
depositing a conductive layer over the barrier layer.

35. The method of claim 34, wherein forming a via comprises:
etching the via in the third dielectric layer using an etch process that is selective for the third dielectric layer over the second dielectric layer; and
etching the via in the second dielectric layer using an etch process that is selective for the second dielectric layer over the third dielectric layer.

36. The method of claim 34, wherein a dielectric constant of the first dielectric layer is less than a dielectric constant of the second dielectric layer.

37. The method of claim 36, wherein forming a via comprises:
etching the via in the third dielectric layer using an etch process that is selective for the third dielectric layer over the second dielectric layer; and
etching the via in the second dielectric layer using an etch process that is selective for the second dielectric layer over the third dielectric layer.

38. The method of claim 37, wherein selectively depositing a metal passivation layer comprises electroless deposition of the metal passivation layer.

39. The method of claim 37, wherein selectively depositing a metal passivation layer comprises selectively chemical vapor depositing a metal selected from the group consisting of tungsten, tantalum nitride, titanium nitride, titanium silicon nitride, or a combination thereof.

40. The method of claim 37, wherein selectively depositing a metal passivation layer comprises:
depositing a copper alloy;
depositing a copper layer over the copper alloy; and
annealing the copper alloy.
